(19) United States
(12) Patent Application Publication
(10) Pub. No.: US 2006/0126687 A1
(43) Pub. Date: Jun. 15, 2006

(54) Method for producing a buried tunnel junction in a surface-emitting semiconductor laser

(75) Inventor: Marcus-Christian Amann, Wohnsitz Munchen (DE)

Correspondence Address: LATHROP & GAGE LC, 4845 PEARL EAST CIRCLE, SUITE 300, BOULDER, CO, 80301, US

(73) Assignee: Vertilas GmbH

(21) Appl. No.: 10/535,688

(22) PCT Filed: Nov. 6, 2003
(86) PCT No.: PCT/EP03/12433

§ 371 Date: Dec. 28, 2005

(30) Foreign Application Priority Data
Nov. 12, 2002 (DE) 102 55 307.6
Feb. 7, 2003 (DE) 103 05 079.5

(51) Int. Cl. H01S 5/00

(52) U.S. Cl. 372/43.01

(57) ABSTRACT

Methods for producing buried tunnel junctions in surface-emitting semi-conductor lasers and devices incorporating the buried tunnel junctions are disclosed. The laser comprises an active zone containing a pn-junction, surrounded by a first n-doped semi-conductor layer and at least one p-doped semi-conductor layer. In addition to a tunnel junction on the p-side of the active zone, the tunnel junction borders a second n-doped semi-conductor layer. For burying the tunnel junction, the layer provided for the tunnel junction is removed laterally in a first step using material-selective etching until the desired diameter is achieved and then heated in a second step in a suitable atmosphere until the etched region is sealed by mass transport from at least one of the semi-conductor layers bordering the tunnel junction. This enables surface-emitting laser diodes to be produced in high yields with stabilization of the lateral single-mode operation and high performance.

### RELATED APPLICATIONS

This application claims the benefit of priority to PCT/EP2003/012433, filed Nov. 6, 2003, which claimed priority to German patent application serial numbers 102 55 307.6 and 103 05 079.5, filed Nov. 27, 2002 and Feb. 7, 2003; each of these applications is incorporated herein by reference.

### BACKGROUND

Surface-emitting laser diodes or Vertical-Cavity Surface-Emitting Lasers (VCSELs) are semi-conductor lasers, in which light emission occurs perpendicular to the surface of the semi-conductor chip. Compared to conventional edge-emitting laser diodes, surface-emitting laser diodes have several advantages such as low electrical power consumption, the possibility of direct checking of the laser diode on the wafer, simple coupling options to the glass fiber, production of longitudinal single mode spectra and the possibility of interconnection of the surface-emitting laser diodes to a two-dimensional matrix.

In the field of fiberoptic communications technology—because of wavelength dependent dispersion or absorption—devices producing radiation in a wavelength range of approximately 1.3 to 2 μm, and in particular wavelengths of about 1.31 μm or 1.55 μm, are needed. Longwave laser diodes with useful properties, especially for the wavelength range above 1.3 μm, have been produced using InP-based connection semiconductors. GaAs-based VCSELs are suitable for the shorter wavelength range of <1.3 μm.

A continuous-wave VCSEL, which emits power of 1 mW at 1.55 μm has been constructed of an InP-substrate with metamorphic layers or mirrors (IEEE Photonics Technology Letters, Volume 11, Number 6, June 1999, pp. 629-631). A VCSEL emitting continuously at 1.526 μm was produced using a wafer connection of an InP/InGaAsP-active zone with GaAs/AlGaAs mirrors (Applied Physics Letters, Volume 78, Number 18, pp. 2632 to 2633 of Apr. 30, 2001). A VCSEL with an air—semi-conductor mirror (InP—air gap distributed Bragg reflectors (DBRs)) was proposed in IEEE ISLC 2002, pp. 145-146. In that case, a tunnel contact (viz. tunnel junction) was formed between the active zone and the upper DBR mirror, whereby a current limitation was achieved by undercutting the tunnel junction layer. The air gap surrounding the remaining tunnel junction zone was used for wave guidance of the optical field. In addition, a VCSEL with antimonide-based mirrors, in which an undercut InGaAs active zone is enclosed by two n-doped InP layers, at which AlGaAsSb DBR mirrors abut, is known (26^{th} European Conference on Optical Communication, ECOC 2000, “88° C., Continuous-Wave Operation of 1.55 μm Vertical-Cavity Surface-Emitting Lasers”).

The optimum properties with regard to output, operating temperature range and modulation bandwidth are exhibited, however, by VCSELs with buried tunnel contacts/buried tunnel junctions (BTJ). The production and structure of a conventional buried tunnel junction will be presented hereinafter with reference to FIG. 1. Using molecular beam epitaxy (MBE) a highly doped p⁺/n⁺ layer pairing 101, 102 is produced with minimal band separation. The tunnel junction 103 is formed between these layers. Using reactive ion etching (RIE), a circular or ellipsoid zone is formed essentially by the n⁺-doped layer 102, the tunnel junction 103 and part of or the entire p⁺-doped layer 101. This zone is covered in a second epitaxy procedure with n-doped InP (layer 104), so that the tunnel junction 103 is “buried”. The contact zone between the covering layer 104 and the p⁺-doped layer 101 acts as a boundary layer when a voltage is applied. The current flows through the tunnel junction with resistances of typically 3×10⁻⁶ Ωcm². In this fashion, the current flow can be restricted to the actual area of the active zone 108. In addition, heat production is low, because the current flows from a high-ohmic p-doped to a low-ohmic n-doped layer.

The overgrowth of the tunnel junction in a conventional BTJ design results in slight variations in thickness, which act unfavorably on lateral wave guiding, so that occurrence of high lateral modes is facilitated, especially in the case of larger apertures. Therefore, only small apertures can be used with less corresponding laser power for single mode operation, which is required in glass fiberoptic communication technology. A further drawback of the conventional design is the use of double epitaxy, which is required for overgrowth of the buried tunnel junction.

Examples and applications of VCSELs with buried tunnel junctions can be found, for example, in “Low-threshold index-guided 1.5 μm long wavelength vertical-cavity surface-emitting laser with high efficiency”, Applied Physics Letter, Volume 76, Number 16, pp. 2179-2181 of Apr. 17, 2000; in “Long Wavelength Buried Tunnel Junction Vertical-Cavity Surface-Emitting Lasers”, Adv. in Solid State Phys. 41, 75 to 85, 2001; in “Vertical-cavity surface-emitting laser diodes at 1.55 μm with large output power and high operation temperature”, Electronics Letters, Volume 37, Number 21, pp. 1295-1296 of Oct. 11, 2001; in “90° C. Continuous-Wave Operation of 1.83 μm Vertical-Cavity Surface-Emitting Lasers”, IEEE Photonics Technology Letters, Volume 12, Number 11, pp. 1435 to 1437, November 2000 and in “High-speed modulation up to 10 Gbit/s with 1.55 μm wavelength InGaAlAs VCSELs”, Electronics Letters, Volume 38, Number 20, Sep. 26, 2002.

The structure of the InP-based VCSEL presented in the aforementioned literature will be briefly explained below with reference to FIG. 2.

The buried tunnel junction (BTJ) in this structure is arranged in reverse relative to the conventional BTJ design described with reference to FIG. 1. The active zone 106 is placed above the tunnel junction with a diameter DBTJ defined by the p⁺-doped layer 101 and the n⁺-doped layer 102. The laser beam exits in the direction indicated by the arrow 116. The active zone 106 is surrounded by a p-doped layer 105 (InAlAs) and a n-doped layer 108 (InAlAs). The facial side mirror 109 over the active zone 106 consists of an epitaxial DBR with 35 InGaAlAs/InAlAs layer pairs, whereby a reflectivity of approximately 99.4% results. The posterior mirror 112 includes a stack of dielectric layers as DBRs and is closed off by a gold layer, whereby a reflectivity of almost 99.75% results. An insulating layer 113 prevents the direct contact of the n-InP layer 104 with the p-side contact layer 114, which is generally comprised of gold or silver (in this context see DE 101 07 349 A1).

The combination comprised of the dielectric mirror 112, the integrated contact layer 114 and the heat sink 115 results in a significantly increased thermal conductivity compared to epitaxial multi-layer structures. Current is injected via the contact layer 114 or via the integrated heat sink 115 and the n-side contact points 110. Express reference is again made to the literature cited above for further details relating to the production and properties of the VCSEL types represented in FIG. 2.

### SUMMARY

An InP-based surface-emitting laser diode with a buried tunnel junction (BTJ-VCSEL) may be produced more economically and in higher yield, and such that the lateral single-mode operation is stable even with larger apertures, whereby an overall higher single-mode output is possible.

In an embodiment, a method for producing a buried tunnel junction in a surface-emitting semi-conductor laser, which has a pn-transition with an active zone surrounded by a first n-doped semi-conductor layer and at least one p-doped semi-conductor layer and a tunnel junction on the p-side of the active zone, which borders on a second n-doped semi-conductor layer, provides for the following steps. In a first step the layer intended for the tunnel junction is laterally ablated by means of material-specific etching up to the desired diameter of the tunnel junction, so that an etched gap remains, which surrounds the tunnel junction. In a second step, the tunnel junction is heated in a suitable atmosphere until the etched gap is closed by mass transport from at least one semi-conductor layer bordering the tunnel junction. The semi-conductor layers bordering the tunnel junction are the second n-doped semi-conductor layer on the side of the tunnel junction facing away from the active zone and a p-doped semi-conductor layer on the side of the tunnel junction facing the active zone.

### BRIEF DESCRIPTION OF THE FIGURES

FIG. 1 is a diagrammatic representation of a buried tunnel junction in a prior art surface-emitting semi-conductor laser.

FIG. 2 is a diagrammatic representation of a cross-section through a prior art surface-emitting semi-conductor laser with a buried tunnel junction (BTJ-VCSEL).

FIG. 3 represents a diagrammatic cross-sectional view of an epitaxial initial structure for a mass transport VCSEL (MT-VCSEL) according to an embodiment.

FIG. 4 represents the structure of FIG. 3 with a formed stamp.

FIG. 5 represents the structure of FIG. 3 with a more deeply formed stamp.

FIG. 6 represents the structure according to FIG. 4 after undercutting of the tunnel junction layer.

FIG. 7 represents the structure according to FIG. 6 after the mass transport process.

FIG. 8 represents a diagrammatic cross-sectional view of a MT-VCSEL according to an embodiment.

FIG. 9 represents one embodiment of an epitaxial intitial structure.

FIG. 10 represents a diagrammatic cross-sectional view of a MT-VCSEL according to an embodiment.

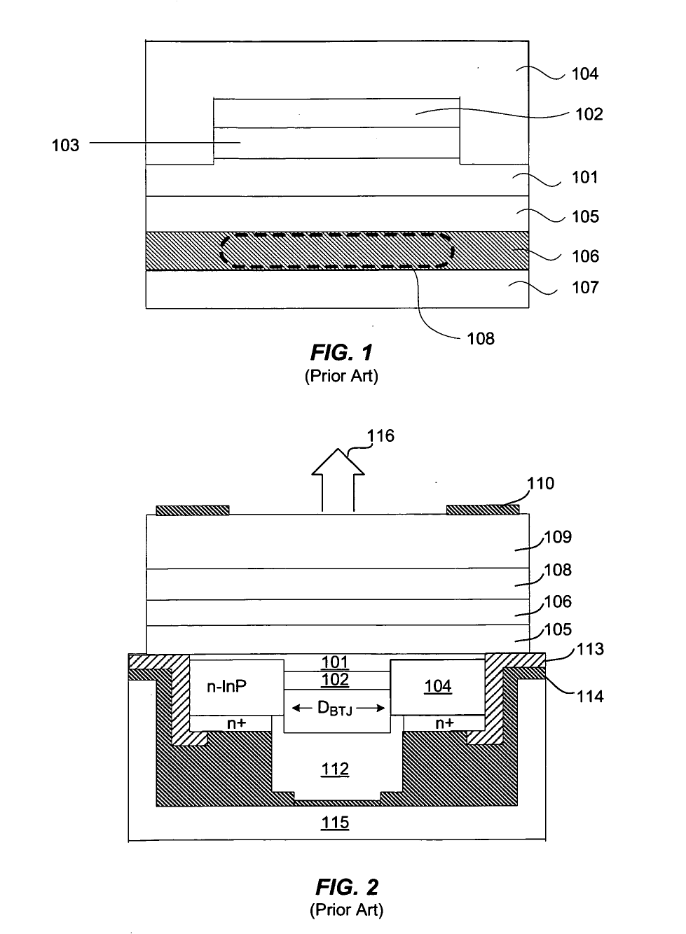

### DETAILED DESCRIPTION

Use of a mass transport technique (MTT) solves both the problem of double epitaxy and that of the built-in lateral wave guide. The MTT replaces the second epitaxy process and thereby avoids the otherwise lateral thickness variation that occurs, with the consequence of a strong lateral wave guide. Burying the tunnel junction no longer occurs by overgrowth but by undercutting the tunnel junction layer and then closing the etched zone by means of mass transport from adjacent layers. In this way, surface-emitting laser diodes can be produced more economically and in higher yields. In addition, lateral single-mode operation is stabilized even with larger apertures, which results in higher single-mode performance.

The mass transport technique was utilized in another context in the early 1980's for producing buried active zones for the so-called buried heterostructure (BH) laser diodes based on InP (see “Study and application of the mass transport phenomenon in InP”, Journal of Applied Physics 54(5), May 1983, pp. 2407-2411 and “A novel technique for GaInAsP/InP buried heterostructure laser fabrication” in Applied Physics Letters 40(7), Apr. 1, 1982, pp. 568-570). The method was, however, found to be unsatisfactory because of considerable degradation problems. Degradation of the BH laser produced by means of MTT was due to the erosion of the lateral etched flanks of the active zone, which cannot be adequately qualitatively protected by MTT. Express reference is made to the aforementioned literature citations for details and implementation of the mass transport technique.

It has been found that the aforementioned aging mechanism in the mass transport technique, which obstructed realization of usable BH lasers, does not play a detrimental role in the imbedding of tunnel junctions, because in BTJ-VCSELs there is no highly excited electron-hole-plasma as in an active zone of the laser and consequently surface-emitting combinations that cause degradation problems do not occur.

Mass transport VCSELs (MT-VCSELs) make it possible to produce technically simpler and better—in terms of the maximum single-mode performance—longwave VCSELs, especially on an InP basis.

In an embodiment, the mass transport process is carried out in a phosphoric atmosphere comprised of H₂ and PH₃, for example, during heating of the component. The preferred temperature range is between 500 and 800° C., preferably between 500 and 700° C. An option in the mass transport technique is to treat the wafer with H₂ and PH₃ in a flowing atmosphere during heating to 670° C. and then hold the temperature for an additional period (total treatment duration is about one hour). Experiments with InP layers in a hydrogen atmosphere also resulted in a mass transport of InP.

The mass transport technique (MTT) may be practiced with at least one of the aforementioned semi-conductor layers that border the tunnel junction comprised of a phosphide compound, in particular InP.

Because of the mass transport process, the etched gap closes and thus buries the tunnel junction. Owing to the high band separation of InP and the low doping, the zones adjacent to the tunnel junction and closed by the mass transport do not represent tunnel junctions and therefore block the current flow. On the other hand, these zones contribute substantially to thermal dissipation because of the high thermal conductivity of InP.

A surface-emitting laser diode may be produced on an epitaxial initial structure to which is sequentially applied a p-doped semi-conductor layer on the p-side of the active zone, the layer intended for the tunnel junction and then the second n-doped semi-conductor layer. Initially a circular or ellipsoid stamp is formed by means of photolithography and/or etching (reactive ion etching (RIE), for example). The flanks (i.e., top and bottom) of the stamp enclose the second n-doped semi-conductor layer and the layer provided for the tunnel junction, when viewed perpendicular to the longitudinal axes of the layers, and extend at least to below the tunnel junction layer. Undercutting of the tunnel junction layer and burying of the tunnel junction are then accomplished by means of mass transport.

The structure obtained in this fashion is ideally suited for producing surface-emitting laser diodes.

In one embodiment, a further semi-conductor layer is provided, which communicates on the p-side of the active zone at the second n-doped semi-conductor layer at which the side of the tunnel junction is facing away from the active zone. This additional semi-conductor layer itself borders on a third n-doped semi-conductor layer, where this further semi-conductor layer is also initially ablated by means of material-selective etching laterally up to a desired diameter and then heated in a suitable atmosphere until the etched gap is closed by mass transport from at least one of the n-doped semi-conductor layers adjacent to the additional semi-conductor layer.

The lateral material-selective etching and the mass transport processes may be done at the same time for the additional semi-conductor layer and the buried tunnel junction.

If a material—such as, for example, InGaAsP—is used for the additional semi-conductor layer that is different from that of the tunnel junction—such as, for example, InGaAs—advantage can be taken of a different lateral etching, whereby the lateral wave guide as defined by the diameter of the additional semi-conductor layer can become wider than the active zone, whose diameter corresponds to the diameter of the tunnel junction. This embodiment thus makes possible a controlled adjustment of the lateral wave guide that is separate from the current aperture. For this purpose the additional semi-conductor layer is not arranged in a node but in an antinode (maximum) of the longitudinal electrical field.

The band gap of the additional semi-conductor layer should be larger than that of the active zone, in order to prevent optical absorption.

A wet chemical etching process using H₂SO₄:H₂O₂:H₂O etching solution in a ratio of 3:1:1 to 3:1:20 may be used for material-selective etching, if the tunnel junction is comprised of InGaAs, InGaAsP or InGaAlAs.

A buried tunnel junction in a surface-emitting semi-conductor produced according to the present method has a number of advantageous features. In comparison to methods involving two epitaxy processes, only one epitaxy process is necessary and consequently the laser diodes are more economical and can be produced with higher yields. When using InP for the mass transport process, the lateral zones enclose the tunnel junction and block the current flow laterally from the tunnel junction, while at the same time contributing appreciably to thermal conduction into the adjacent layers. In addition, a surface-emitting semi-conductor prepared by the present method has only a very low built-in wave guide, which facilitates stabilization of the lateral single-mode operation even with larger apertures and thus overall higher single-mode performances result.

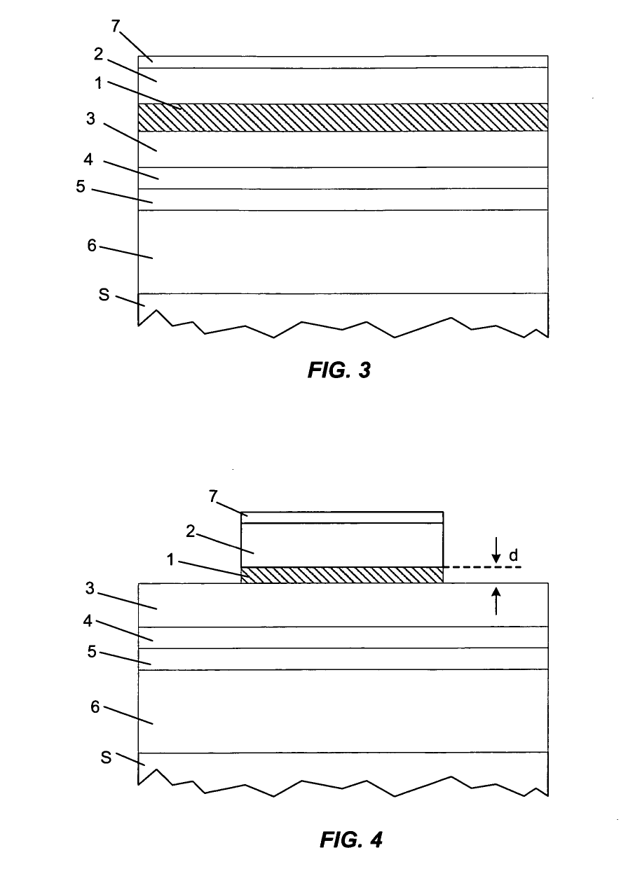

FIG. 3 diagrammatically represents an epitaxial initial structure for a MT-VCSEL according to an embodiment. Starting with the InP substrate S and in sequence a n-doped epitaxial Bragg mirror 6, an active zone 5, an optional p-doped InAlAs layer 4, a p-doped bottom InP layer 3, a tunnel junction 1 comprised of at least one each of a high p- and n-doped semi-conductor layer, which is situated in a node (minimum) of the longitudinal electrical field, a n-doped upper InP layer 2 and a n⁺-doped upper contact layer 7 are deposited.

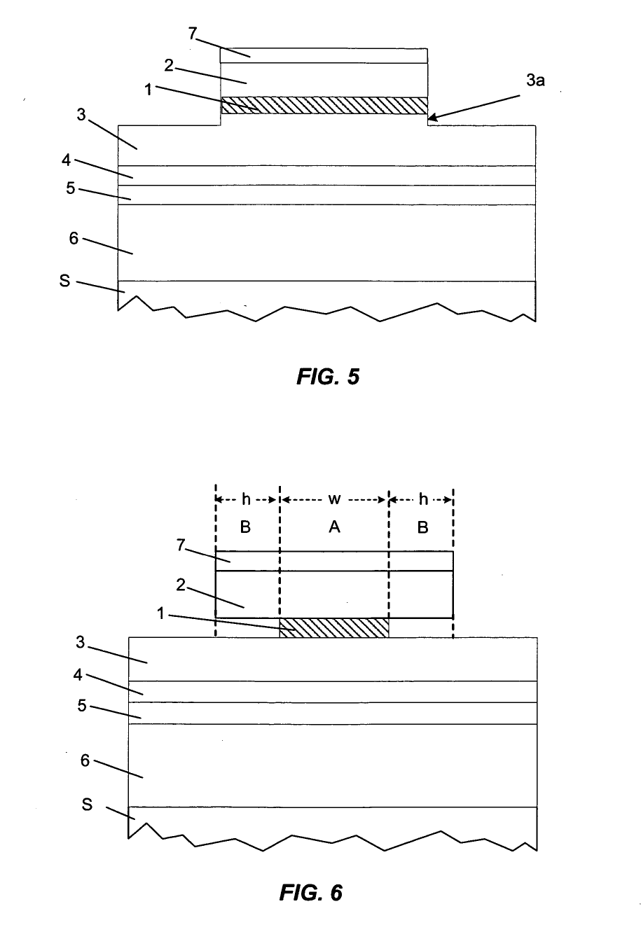

A circular or ellipsoid stamp is produced, by means of photolithography and/or etching, on a wafer having an initial structure according to FIG. 3. Exemplary stamps are shown in cross-section in FIGS. 4 and 5. The stamps extend at least to underneath the tunnel junction 1, which has a thickness d (see FIG. 4), or to the lower p-InP layer 3 (FIG. 5), whereby an edge 3a is etched into layer 3. The stamp diameter (w+2h) is typically approximately 5 to 20 μm larger than the aperture diameter, w, which is typically 3 to 20 μm, such that h is approximately 3 to 10 μm. In this embodiment h (see FIG. 6) represents the width of the under cut zone B of the layer provided for the tunnel junction 1.

As shown in FIG. 6, the tunnel junction 1 is ablated laterally by means of material-selective etching, without etching the layers, the n-doped upper InP layer 2 and the p-doped lower InP layer 3, surrounding it. The lateral undercutting of the tunnel junction 1 (or the layer intended for the tunnel junction) of typically h=2 to 10 μm is used for defining the aperture A, which corresponds to the remaining tunnel contact area. The material-selective etching is, for example, possible using wet chemistry with a H₂SO₄:H₂O₂:H₂O etching solution in a ratio of 3:1:1 to 3:1:20, if the tunnel junction 1 is comprised of InGaAs, InGaAsP or InGaAlAs.

In order to obtain a buried tunnel junction 1 having the structure shown in FIG. 6, the gap etched in zone B laterally surrounding the tunnel junction 1 is closed by means of a mass transport process. The wafer having the structure shown in FIG. 6, is heated under a phosphoric atmosphere at 500 to 600° C. Typical heating times are 5 to 30 minutes. During this process, small amounts of InP move from the upper and/or lower InP layer 2 and/or 3, respectively, into the previously etched gap, which as a result closes.

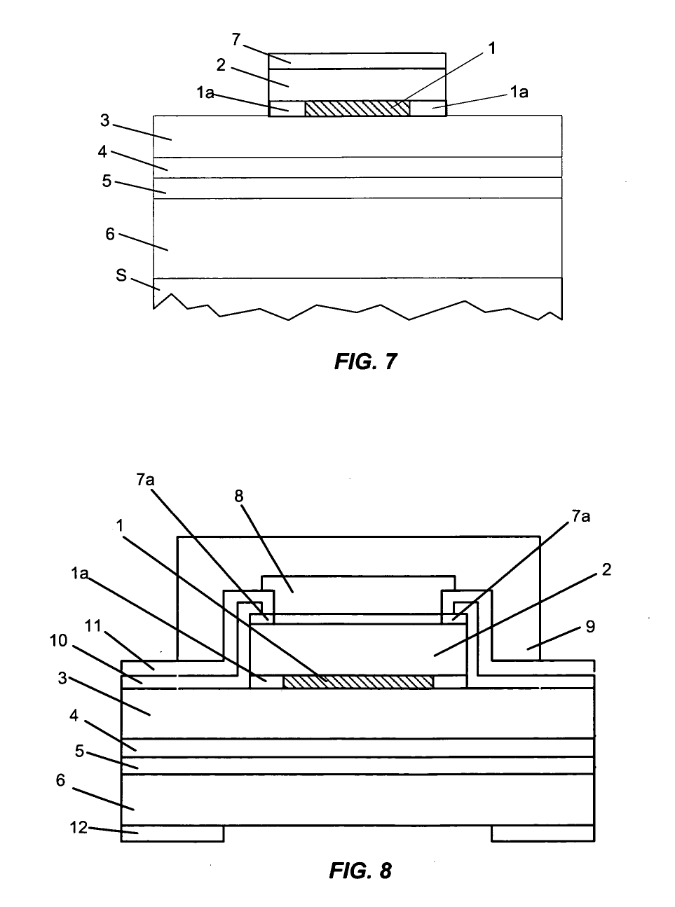

The result of the mass transport process is shown in FIG. 7. The transported InP in zone 1a closes the tunnel junction 1 laterally (buries it). Because of the high band separation of InP and the low doping, zones 1a do not represent tunnel junctions and therefore block the current flow. Accordingly the zone crossed by current of the active zone 5 having the diameter w (see FIG. 6) corresponds substantially to the area (aperture A in FIG. 6) of the tunnel junction 1. On the other hand, the annular zones 1a comprised of InP and having the annular width h contribute, because of the high thermal conductivity of InP, substantially to thermal dissipation via the upper InP layer 2.

Further processing of the structure according to FIG. 7 to obtain the finished MT-VCSEL corresponds to techniques well-known from the BTJ-VCSELs, as they are described above and in the cited literature, and will not be described in more detail here. FIG. 8 shows a finished MT-VCSEL including an integrated gold heat sink 9 surrounding a dielectric mirror 8, which borders the upper n-doped InP layer 2. An annular structured n-side contact layer 7a is disposed around the base of the dielectric mirror 8. An insulation and passivation layer 10 composed of, for example, Si₃N₄ or Al₂O₃, protects both the p-doped lower and the n-doped upper InP layers 3, 2 from direct contact with the p-side contact 11 or the gold heat sink 9. The p-side contact 11 and the n-side contact 12 may be made of Ti/Pt/Au, for example.

In an embodiment the active zone 5, which is shown as a homogeneous layer, is comprised of a layered structure of 11 thin layers, for example (5 quantum film layers and 6 barrier layers).

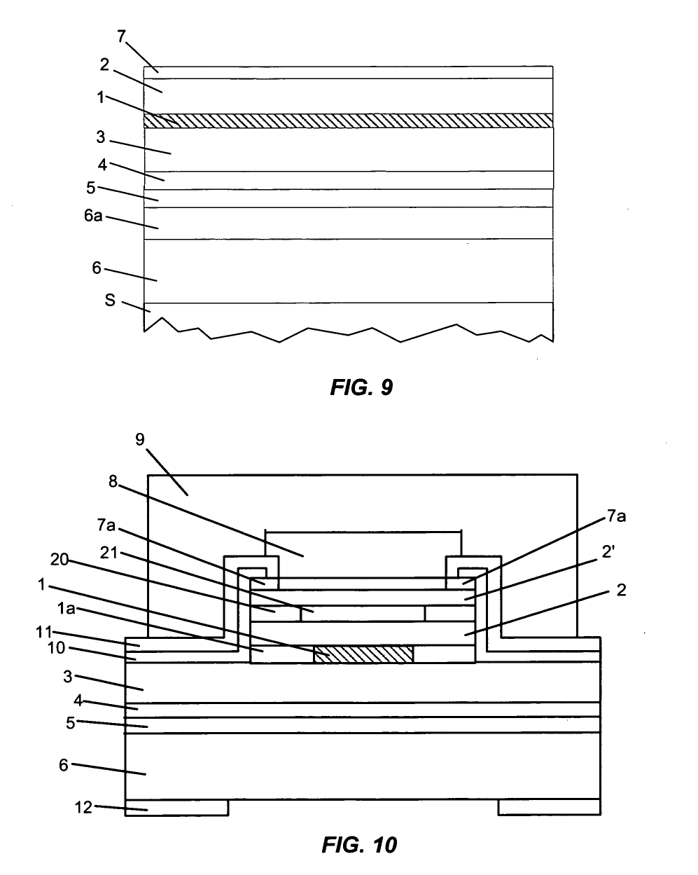

In FIG. 9, an embodiment of an epitaxial initial structure is represented where an additional n-doped InP layer 6a is inserted underneath the active zone 5. This layer reinforces the lateral thermal drainage from the active zone 5 and accordingly reduces its temperature.

Another embodiment is shown in FIG. 10. The mass transport technique is applied in two overlying layers, where a single mass transport process may be implemented both for the tunnel junction layer and for the additional semi-conductor layer 21. In FIG. 10, this additional semi-conductor layer 21 is arranged above the tunnel junction 1. The additional semi-conductor layer 21 borders on two n-doped InP layers, 2, 2′. Zone 20 laterally encompassing the additional semi-conductor layer 21 may be composed of InP, deposited by mass transport, that closes an undercut zone.

Insofar as the index of refraction of the additional semi-conductor layer 21 differs from the surrounding InP, this layer 21 generates a controlled lateral wave guide. For this purpose the additional semi-conductor layer is not arranged in a node but in an antinode (maximum) of the longitudinal electrical field. When using different semi-conductors such as, for example, InGaAs for the tunnel junction 1 and InGaAsP for the additional semi-conductor layer 21, a different lateral etching composition can be used. In this way, the lateral wave guide, which is defined by the diameter of the layer 21, can be wider than the active range of the active zone 5, whose diameter is equivalent to the diameter of the tunnel junction 1. This embodiment thus makes possible a controlled adjustment of the lateral wave guide that is separate from the current aperture.

1. A method for producing a buried tunnel junction in a surface-emitting semi-conductor laser having an active zone with a pn-junction surrounded by a first n-doped semi-conductor layer and at least one p-doped semi-conductor layer and having a tunnel junction on the p-side of the active zone, which borders on a second n-doped semi-conductor layer comprising:
laterally ablating tunnel junction material by material-selective etching to a desired diameter of the tunnel junction; and heating the semi-conductor in a suitable atmosphere, until an etched gap formed by the ablating procedure is closed by mass transport from at least one semi-conductor layer bordering the tunnel junction.

2. The method according to claim 1, wherein at least one of the semi-conductor layers bordering the tunnel junction comprises a phosphide compound.

3. The method according to claim 1, wherein the suitable atmosphere comprises a phosphoric atmosphere.

4. The method according to claim 1, wherein heating is in a temperature range of about 500 to 800° C.

5. The method according to claim 1, further comprising:
starting with an epitaxial initial structure on the surface-emitting semi-conductor laser;
sequencially applying a p-doped semi-conductor layer, the tunnel junction layer and the second n-doped semi-conductor layer on the p-side of the active zone; and using photolithography and/or etching to form a circular or ellipsoid stamp having flanks enclosing the second n-doped semi-conductor layer and the tunnel junction layer and extending at least to underneath the tunnel junction, layer.

6. The method according to claim 1, further comprising applying an additional semi-conductor layer to the second n-doped semi-conductor layer at the p-side of the active zone, the additional semi-conductor layer bordering a third n-doped semi-conductor layer, wherein the additional semi-conductor layer is laterally ablated to a desired diameter by material-selective etching and subsequently heated in a suitable atmosphere until an etched gap formed by the ablating procedure is closed by mass transport from at least one of the semi-conductor layers bordering the additonal semi-conductor layer.

7. The method according to claim 6, wherein different semi-conductors are used for the additional semi-conductor layer and for the tunnel junctions.

8. The method according to claim 7, wherein InGaAsP is used for the additional semi-conductor layer and InGaAs is used for the tunnel junction.

9. The method according to claim 6 wherein the additional semi-conductor layer is arranged in a maximum of a longitudinal electrical field, while the tunnel junction is in a minimum of the longitudinal electrical field.

10. The method according to claim 1, wherein for a material-selective etching solution is H₂SO₄: H₂O₂: H₂O used as in a ratio of 3:1:1 to 3:1:20, if the tunnel junction is comprised of InGaAs, InGaAsP or InGaAlAs.

11. A surface-emitting semi-conductor laser having an active zone with a pn-junction surrounded by a first n-doped semi-conductor layer and at least one p-doped semi-conductor layer and a tunnel junction on the p-side of the active zone, which borders a second n-doped semi-conductor layer, wherein the tunnel junction is laterally flanked by a zone, which connects the second n-doped semi-conductor layer with one of the p-doped semi-conductor layers and which is formed from at least one of these adjacent layers by mass transport.

12. The surface-emitting semi-conductor laser according to claim 11, wherein at least one of the semi-conductor layers bordering the tunnel junction comprises a phosphide compound.

13. The surface-emitting semi-conductor laser according to claim 11, wherein the p-doped semi-conductor layer comprises InAlAs which is flanked by a p-doped InP layer and the active zone.

14. The surface-emitting semi-conductor laser according to claim 11 wherein the tunnel junction his arranged in a minimum of a longitudinal electrical field.

15. The surface-emitting semi-conductor laser according to claim 11 wherein an additional n-doped semi-conductor layer is present between the active zone and the first n-doped semi-conductor layer, which is configured as a semi-conductor mirror.

16. The surface-emitting semi-conductor laser according to claim 11 wherein an additional semi-conductor layer is present, which abuts the second n-doped semi-conductor layer bordering the tunnel junction and which itself borders a third n-doped semiconductor layer, whereby this additional semi-conductor layer is laterally surrounded by a zone that connects the second n-doped semi-conductor layer with the third n-doped doped semi-conductor layer and is generated by mass transport from at least one of these two layers.

17. The surface-emitting semi-conductor laser according to claim 16, wherein the refractive index of the additional semi-conductor layer differs from those of the second n-doped semi-conductor layer and the third n-doped semi-conductor layer.

18. A surface emitting semi-conductor laser according to claim 16 wherein the additional semi-conductor layer is arranged in a maximum of a longitudinal electrical field.

19. The surface emitting semi-conductor laser according to claim 16 wherein the additional semi-conductor layer and the tunnel junction are comprised of different semi-conductor materials.

20. The surface-emitting semi-conductor laser according to claim 19, wherein the additional semi-conductor layer is comprised of InGaAsP and the tunnel junction is comprised of InGaAs.

21. The surface-emitting semi-conductor laser according to claim 16, wherein the diameter of the additional semi-conductor layer is greater than that of the tunnel junction.

22. The surface-emitting semi-conductor laser according to claim 16 wherein the band gap of the additional semi-conductor layer is greater than the band gap of the active zone.

23. The method according to claim 1, wherein at least one of the semi-conductor layers bordering the tunnel junction comprises InP.

24. The method according to claim 1, wherein the suitable atmosphere comprises a mixture of PH₃ and hydrogen.

25. The method according to claim 1, wherein heating is in a temperature range of about 500 to 600° C.

26. The surface-emitting semi-conductor laser according to claim 11, wherein at least one of the semi-conductor layers bordering the tunnel junction comprises InP.
